(19) United States
(12) Patent Application Publication
(10) Pub. No.: US 2010/0200971 A1
(43) Pub. Date: Aug. 12, 2010

(54) High current capacity inner leads for semiconductor device

(76) Inventor: Solomon David Edlin, Rishon Lezion (IL)

Correspondence Address: Edlin Solomon, P.O. Box 15075, Rishon Lezion, 75050, IL

(21) Appl. No.: 12/657,428

(22) Filed: Jan. 21, 2010

(30) Foreign Application Priority Data
Jan. 21, 2009 (IL) IL 196635

(51) Int. Cl. H01L 23/495

(52) U.S. Cl. 257/675; 257/E23.051

(57) ABSTRACT

The invention can be used for improving performance of laser diodes, solar cells, microprocessors and other devices. The invention enables to create semiconductor devices having a great area of die, a great number of leads, a high operating current and a high heat dissipation. This is achieved by the following manner: offered leads are made of copper foil; the rigidity of the foil is decreased by means of disposing of alternating parallel narrow trenches on both sides of the foil; the offered leads are microspring; additional decreasing of rigidity can be achieved by the bending of foil along wide trenches that are created for this aim. Offered leads can be directly connected to the die.

The invention relates to microelectronics and more particularly to the structure of inner leads of semiconductor devices and integral circuits.

### BACKGROUND OF THE INVENTION

The invention enables to create semiconductor devices having a great area of die, a great number of leads, a high operating current and high heat dissipation.

There exists a method for attaching leads to die [1]. Electrical connection is made by a strip of anisotropically conductive elastomeric material, preferably a multilayer laminate consisting of alternating parallel sheets of a conductive foil and an insulating elastomer wherein the laminate layers are oriented perpendicular to both the bond pad and the lead.

There exists a method for fabricating an ultrahigh density compliant chip input/output interconnections [2]. A polymer film with embedded air gaps provides substantially higher compliance than polymer film without embedded air gaps. A chip with 12000 cm.sup.-2 compliant I/O leads are demonstrated.

There exists a method for soldering Si chip to Cu substrate comprising thick layers of solder [3]. The disadvantages are low thermal conductivity and low electrical conductivity because of high thickness of solder (about 10.sup.-4 m).

There exists a bumpless method of attaching inner leads to semiconductor integrated circuits [4]. A lead frame of copper foil is disposed parallel to chip surface. The disadvantage is necessary to heat the inner leads to high temperature.

There exists a method and apparatus for plasma etching of Cu-containing layers in semiconductor devices using an aluminum source in the presence of a halogen-containing plasma [5]. The aluminum source reacts with halogenated Cu-containing surfaces and forms volatile etch products that allows for anisotropic etching Cu-containing layers using conventional plasma etching tools.

There exists an application for power transistor [6]. The transistor has six leads. The transistor provides high current density.

### SUMMARY OF THE INVENTION

The external forces and the coefficient of thermal expansion mismatch between silicon die, materials of package and leads determine the choice of the structure of latter. Offered leads is made of copper foil coated with gold or silver; rigidity of the foil is decreased by means of disposing of alternating parallel narrow trenches on both sides of the foil. The lead becomes a microspring. The narrow trenches can be either perpendicular to contact pads of a semiconductor die or non-perpendicular as well as non-straightforward. A compliance of the lead (FIG. 3) along trenches is low, but the compliance of the lead perpendicular to trenches is high. End of compliant lead can be lightly turn relatively any axis. A decrease of the distance between the next of the trenches and an increase of the depth of the trenches lead to an increase of the compliance of the leads. Hence, it is possible to select necessary rigidity. Shape of trench is inessential.

An additional decrease of rigidity can be achieved by means of bending of the foil along wide trenches, which are created for this aim (flexible leads; microsprings). The leads become compliant and flexible ones. The compliant leads protect the die from high stress.

The offered lead can serves as a power supply bus, signal lead, an interconnection structure, external lead. The offered leads can be connected to external leads that are the part of a package. The area of the section of offered leads is commensurable with an area of the die. Offered leads enable to pass a high current density. Besides, offered flexible leads enable to use the great area of die. Hence, offered leads enable to manufacture semiconductor devices having a high operating current. A decrease of conductivity of the leads because of the trenches is inessential.

The offered leads can be disposed parallel to the die and/or perpendicular to it. The leads can be produced with help of a leadframe. The alone lead or lead stack can be connected to horizontal leadframe with solder to increase current capacity.

The inner leads of integral circuit can be either parallel to each other or non-parallel of ones. The ends of inner leads can be joined a lead connecting strip, a lead-fixing tape or other manners.

The leads can be pack by adhesive bonding. It is necessary to take into consideration a loss of energy in the adhesive bonding at high frequency.

Dry anisotropic etching of narrow and wide trenches (including through), bending, polishing, coating with noble metal and connecting the inner leads to contact pads and external leads are manufactured by known technique, for example, soldering with soft solder.

The barrier film has used to protect the semiconductor die from Cu, Au or Ag doping.

This result is achieved by making at least one of leads of semiconductor device of copper foil comprising alternating narrow trenches on both sides of said foil; said lead is directly connected to at least one of the contact pads of the die.

This result is achieved by creating the distance between the next of said trenches equal to approximately the thickness of said foil.

This result is achieved by creating the depth of said trenches equals about 50 percent of said thickness of said foil.

This result is achieved by creating said trenches parallel to each other and perpendicular to said contact pads.

This result is achieved by creating the length of said trenches equals about 50 percent of the height of said leads.

This result is achieved by creating said trenches non-straightforward.

This result is achieved by creating said height of said lead substantially greater than said thickness of said foil.

This result is achieved by coating said lead with gold or silver.

This result is achieved by connecting said lead to said contact pad with solder; the thickness of said solder equals about 3.times.10.sup.-6 m.

This result is achieved by the fact that said lead is the part of a heatspreader.

This result is achieved by creating the lead stack comprising a plurality of leads of semiconductor device separated each other by the isolation; said leads are made of copper foil comprising alternating narrow trenches on both sides of said foil; said leads are directly connected to the contact pads of the die.

This result is achieved by connecting said lead stack to said contact pads that are a number of parallel strips; said leads are connected to external leads that are the part of a package.

This result is achieved by further comprising alternating parallel wide trenches disposed near the end of inner lead; said leads are bent along said wide trenches.

This result is achieved by creating the leadframe comprising a plurality of inner leads and at least one external leads; said leadframe is made of copper foil; said inner leads comprise alternating narrow trenches on both sides of said foil; said inner leads are directly connected to contact pads of the die.

This result is achieved by creating the distance between the next of said trenches equal to approximately the thickness of said foil.

This result is achieved by creating the depth of said trenches equals about 50 percent of said thickness of said foil.

This result is achieved by coating said leadframe with gold or silver.

This result is achieved by directly connecting said lead stack to said die and said leadframe.

The leads with an offered combination of features are unknown therefore the offered leads correspond to the criterion “novelty”.

The offered combination of features does not obviously follow from the engineering level, technical performance is not known from prior art, therefore the leads correspond to the criterion “invention level”.

The purpose of the invention and the means and methods of its realization are indicated in the application documents, its purpose being realizable, which means there is “industrial applicability”.

### BRIEF DESCRIPTION OF THE DRAWING

FIG. 1 represents the connection of contact pads of die with leads by an anisotropically conductive elastomeric strip (prior art).

FIG. 2 represents the connection of contact pads of die to offered leads.

FIG. 3 represents the disposition of trenches of foil. The first of many embodiments.

FIG. 4 represents the disposition of trenches of foil. The second of many embodiments.

FIG. 5 represents the disposition of trenches of foil. The third of many embodiments.

FIG. 6 represents the disposition of contact pads of power transistor. (Scale has not been kept. One of several variants; for illustration only).

FIG. 7 represents the structure of leads of power transistor. (Scale has not been kept. One of several variants; for illustration only).

FIG. 8 represents the structure of leads of power transistor. (Scale has not been kept. One of several variants; for illustration only).

“New sheet”. FIG. 9 represents a shape of leadframe. (Scale has not been kept. One of many embodiments; for illustration only).

“New sheet”. FIG. 10 represents the connection of contact pads of die to offered leads. (Scale has not been kept. One of many embodiment; for illustration only).

### DETAIL DESCRIPTION OF THE PREFERRED EMBODIMENTS

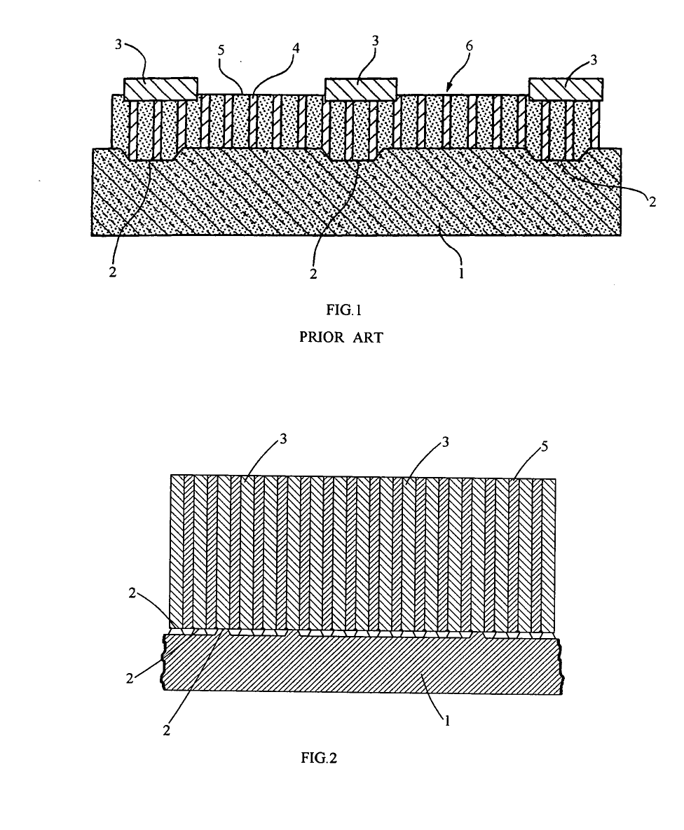

Connection of contact pads with leads FIG. 1 comprises chip 1, contact pad 2, lead 3, conductive foil 4, insulating elastomer 5, anisotropically conductive elastomeric material strip 6.

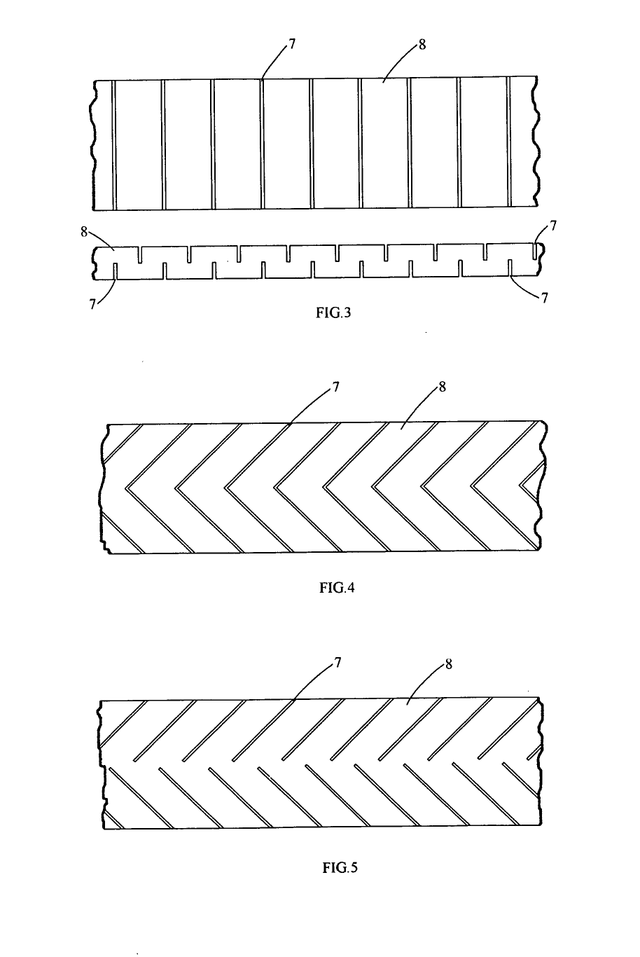

Connection of contact pads with leads FIG. 2 comprises chip 1, contact pad 2, lead 3, isolation 5.

Thickness of the isolating film equal to approximately the thickness of the foil.

Isolation can be made, for example, of polytetrafluoreethylene.

Disposition of trenches FIG. 3 comprises trench 7, foil 8.

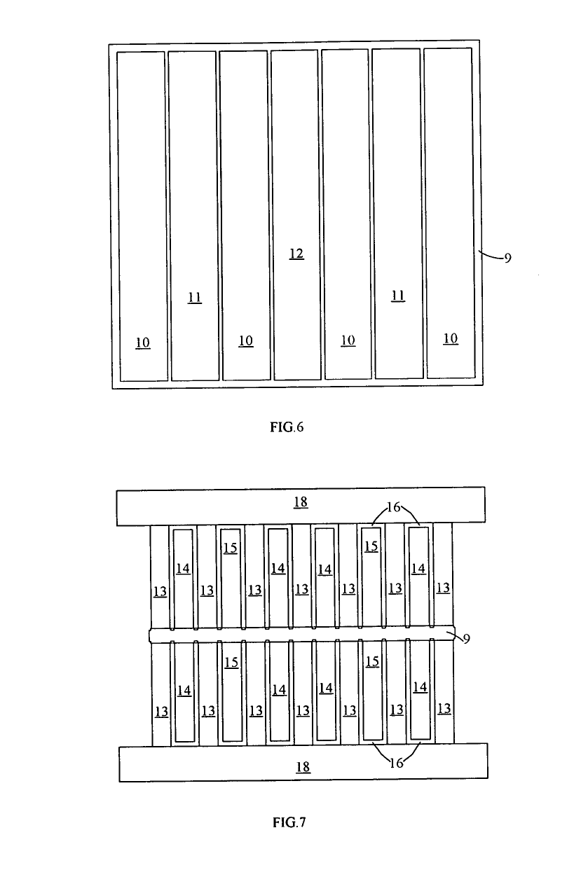

Disposition of trenches on one side of foil FIG. 4 comprises trench 7, foil 8.

Non-straightforward trenches increase compliance of the leads along all directions.

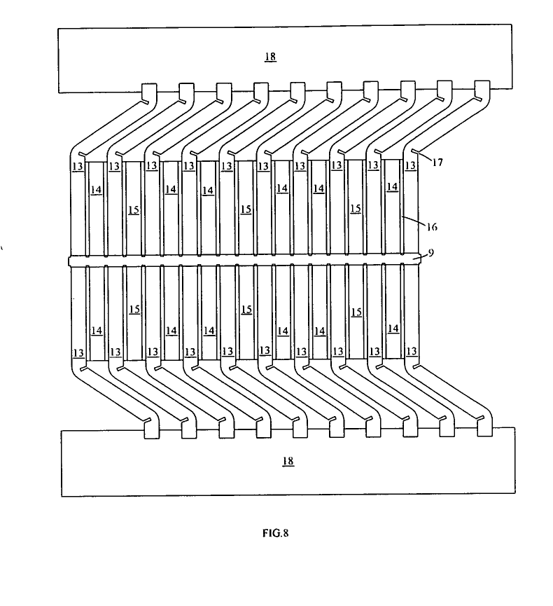

Disposition of trenches on one side of foil FIG. 5 comprises trench 7, foil 8.

Planar view of the die with contact pads FIG. 6 comprises chip 9, ordinary channel contact pads 10, gate contact pads 11, thick channel contact pads 12.

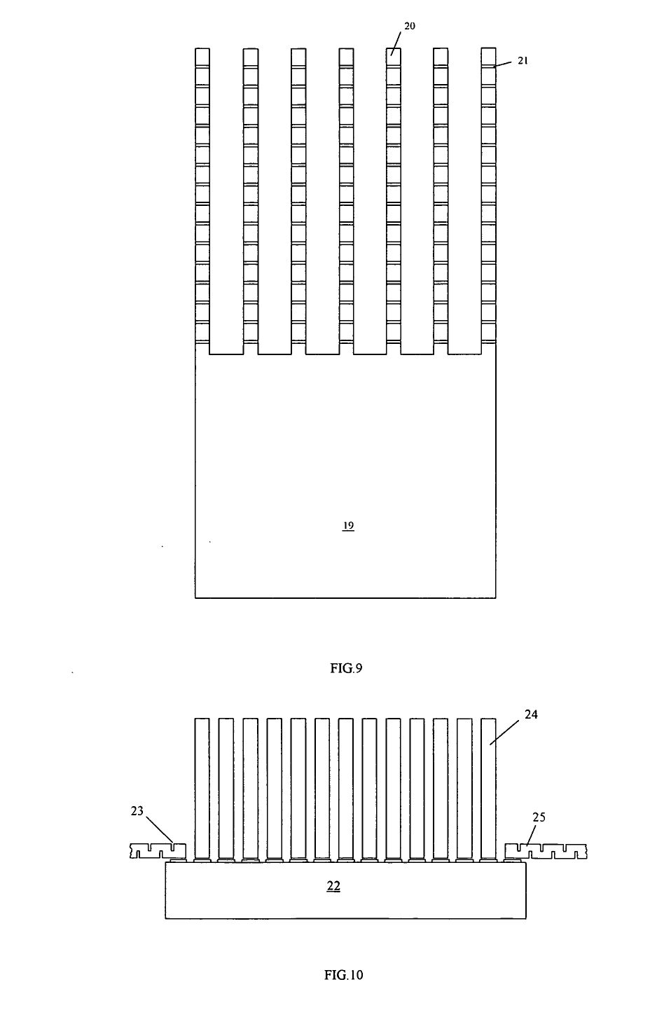

A structure of leads of power transistor FIG. 7 comprises chip 9, inner lead of ordinary channel 13, inner lead of gate 14, inner lead of thick channel 15, isolation 16, external lead of ordinary channel 18 (external leads of gate and thick channel are not shown).

Thickness of the foil is at least a few times greater than thickness of the isolating film. A structure of leads of power transistor FIG. 8 comprises chip 9, inner lead of ordinary channel 13, inner lead of gate 14, inner lead of thick channel 15, isolation 16, wide trench which are parallel to contact pad 17, external lead of ordinary channel 18 (external leads of gate and thick channel are not shown).

A leadframe FIG. 9 comprises external lead 19, inner lead 20, trench 21.

After soldering inner lead 20 is drawn. Relative lengthening equals about 10.sup.-3.

Connection of contact pads with leads FIG. 10 comprises chip 22, trench 23, power supply bus 24, signal lead 25.

Thickness of lead (copper foil) equal to, for example, 35.times.10.sup.-6 m.

Width of narrow trench equal to, for example, 2.times.10.sup.-6 m.

As a rule, height (width) of inner leads can be greater than the thickness of the foil from 2 to 50 times.

While the invention has been particularly shown and described with reference to the preferred embodiments thereof, it will be understood by those skilled in the art that the foregoing and other changes in form and detail may be made therein without departing from the spirit and the scope of the invention.

### REFERENCES

1. Stroupe Huge E. Technique for attaching die to leads. U.S. Pat. No. 7,449,368. H01L 21/00. Priority Oct. 27, 2005.
2. Muhannad S. Bakir et al. Sea of Leads (SoL) Ultrahigh Density Wafer-Lewel Chip Input/Output Interconnections for Gigascale Integration (GSI). IEEE Transactions on electron devices. Vol 50. No 10. October 2003. p. 2039.
3. Jong Sung Kim et al. Ag-Copper Structure for Bonding Large Semiconductor Chips. IEEE Transactions on components and packaging technologies. Vol 31. No 4. December 2008. p. 875.
4. Kondo Toshinari. Bumpless method of attaching inner leads to semiconductor integrated circuits. U.S. Pat. No. 5,885,892. H01L 21/60. Priority Feb. 8, 1996.
5. Ludviksson Audunn et al. Plasma etching of Cu-containing layers. U.S. Pat. No. 7,553,427. C23F 1/00. Priority Apr. 14, 2003.
6. Edlin Solomon. Bidirectional bipolar field effect device. IL Patent application No.176423. H01L 29/45. Priority 20.6.2006.

1. At least one of leads of semiconductor device is made of copper foil comprising alternating narrow trenches on both sides of said foil;
said lead is directly connected to at least one of the contact pads of the die.

2. The lead according to claim 1 wherein the distance between the next of said trenches equal to approximately the thickness of said foil.

3. The lead according to claim 1 wherein the depth of said trenches equals about 50 percent of said thickness of said foil.

4. The lead according to claim 1 wherein said trenches are parallel to each other and perpendicular to said contact pads.

5. The lead according to claim 1 wherein the length of said trenches equals about 50 percent of the height of said leads.

6. The lead according to claim 1 wherein said trenches are non-straightforward.

7. The lead according to claim 1 wherein said height of said lead is substantially greater than said thickness of said foil.

8. The lead according to claim 1 wherein said lead is coated with gold or silver.

9. The lead according to claim 1 wherein said lead is connected to said contact pad with solder; the thickness of said solder equals about 3.times.10.sup.-6 m.

10. The lead according to claim 1 wherein said lead is the part of a heatspreader.

11. A lead stack comprising a plurality of leads of semiconductor device separated each other by the isolation;
said leads are made of copper foil comprising alternating narrow trenches on both sides of said foil;
said leads are directly connected to the contact pads of the die.

12. The lead stack according to claim 11 wherein said lead stack is connected to said contact pads that are a number of parallel strips. Said leads are connected to external leads that are the part of a package.

13. The lead stack according to claim 12 further comprise alternating parallel wide trenches disposed near the end of inner lead. Said leads are bent along said wide trenches.

14. A leadframe comprising a plurality of inner leads and at least one external leads;
said leadframe is made of copper foil;
said inner leads comprise alternating narrow trenches on both sides of said foil;
said inner leads are directly connected to contact pads of the die.

15. The leadframe according to claim 14 wherein the distance between the next of said trenches equal to approximately the thickness of said foil.

16. The leadframe according to claim 14 wherein the depth of said trenches equals about 50 percent of said thickness of said foil.

17. The leadframe according to claim 14 wherein said leads are coated with gold or silver.

18. The leadframe according to claim 14 further comprising said lead stack directly connected to said die and said leadframe.
